(19) United States
(12) Patent Application Publication
(10) Pub. No.: US 2007/0279876 A1
(43) Pub. Date: Dec. 6, 2007

(54) Device for passivating at least one component by a housing and method for manufacturing a device

(76) Inventors: Kurt Weiblen, Metzingen (DE); Martin Schoefthaler, Reutlingen (DE); Thomas Haalboom, Maulbronn (DE)

Correspondence Address: KENYON & KENYON LLP, ONE BROADWAY, NEW YORK, NY, 10004, US

(21) Appl. No.: 11/603,440

(22) Filed: Nov. 21, 2006

(30) Foreign Application Priority Data
Nov. 24, 2005 (DE) 10 2005 055 950.6

(51) Int. Cl. H05K 5/00; H05K 3/30

(52) U.S. Cl. 361/752; 29/854

(57) ABSTRACT

A device for passivating at least one component by a housing and a method for manufacturing the device. A cover is connected to a front side of the substrate to form an inner chamber of the housing in a connection area. The component is attached to the front side of the substrate and inside the inner chamber of the housing, at least one contact line, which is connected in an electrically conductive manner to the component, is electrically insulated in relation to the connection area and is provided in the proximity of at least a part of the connection area between the front side and a rear side of the substrate, which faces away from the front side, or on the rear side of the substrate.

### FIELD OF THE INVENTION

The present invention is directed to a device for passivating at least one component by a housing.

### BACKGROUND INFORMATION

A passive magnetic position sensor is described in German Patent Application DE 19 648 539 A1. It includes a substrate having a resistor network applied to the substrate and a contact structure, which is assigned to the resistor network, and which may be deflected under the effect of a magnetic device, an electrical connection being caused between the resistor network and the contact structure which depends on the position of the magnetic device. The conventional magnetic position sensor is implemented with a housing, one part thereof being provided in the form of an insulating substrate and a further part thereof being provided as a housing cover. This magnetic position sensor has the disadvantage that it is not possible to implement a space-saving and simultaneously hermetically sealed package for an extensive circuit and simultaneously allow contact of a component situated inside the housing to the outside in a simple way.

### SUMMARY

A device according to an example embodiment of the present invention may have the advantage that sufficient passivation of a component is implemented by a housing and, in addition, a good electrical connection, which operates reliably over the entire service life of the device, is made possible between the component and further elements or contact areas situated on the substrate.

The term “in the proximity of at least a part of the connection area” means, e.g., that the contact conductors are guided through the connection area, but are electrically insulated from the connection area.

It is preferable according to the present invention for the housing to be hermetically sealed. This has the advantage that a material exchange between the interior of the housing and the exterior of the housing occurs, if at all, only in a very controlled way and to a very small extent. Furthermore, it is preferable for a predefined atmosphere to be settable in the interior of the housing, in particular with a predefined ambient humidity and/or dew point and in particular with a predefined gas pressure. This has the advantage that in particular for the case in which the component is implemented as a sensor component, such as a micromechanically manufactured sensor component in the form of an acceleration sensor or the like, direct contact between the micromechanical structure of the sensor component and the interior of the housing may be provided and, nonetheless, such a micromechanical component may function in the predefined way over the entire service life.

Furthermore, it is preferable for the substrate to be a circuit board, in particular a ceramic circuit board and in particular an LTCC ceramic circuit board (low temperature co-fired ceramic). It is thus possible in a particularly simple way with manageable technology to achieve both a sufficient seal, in particular a hermetic seal, of the housing and to use a simple and secure bushing to connect the printed conductors and/or contact lines in the substrate through the area of the connection of the substrate to the cover.

Furthermore, it is preferable according to the present invention for the connection area to be provided peripherally on the edge of the cover. It is possible in this way using simple means to implement a complete connection between the substrate and the cover, so that a good seal of the housing may be achieved.

Furthermore, it is preferable for the housing to be closed in the connection area using soldering and/or welding and/or adhesion. An exact and well sealed connection between the cover and the substrate and/or such an implementation of the housing is thus possible using simple methods which may be performed cost-effectively.

A further object of the present invention is to provide a method for manufacturing a device according to the present invention, the component being attached to the substrate in a first step and the cover being connected to the front side of the substrate to form the housing in a second step. It is possible in this way to manufacture a device according to the present invention rapidly and cost-effectively using simple means.

### BRIEF DESCRIPTION OF THE DRAWINGS

Exemplary embodiments of the present invention are illustrated in the figures and explained in greater detail below.

FIG. 1 shows a schematic view of a preliminary stage of an example device according to the present invention in a perspective illustration.

FIG. 2 shows a top view and a sectional illustration of a schematic illustration of the example device according to the present invention.

FIG. 3 shows a schematic illustration of the connection of a cover to a substrate according to a first embodiment of the example device according to the present invention.

FIG. 4 shows a schematic illustration of the connection of the cover to the carrier plate according to a second example embodiment of the device according to the present invention.

### DETAILED DESCRIPTION OF EXAMPLE EMBODIMENTS

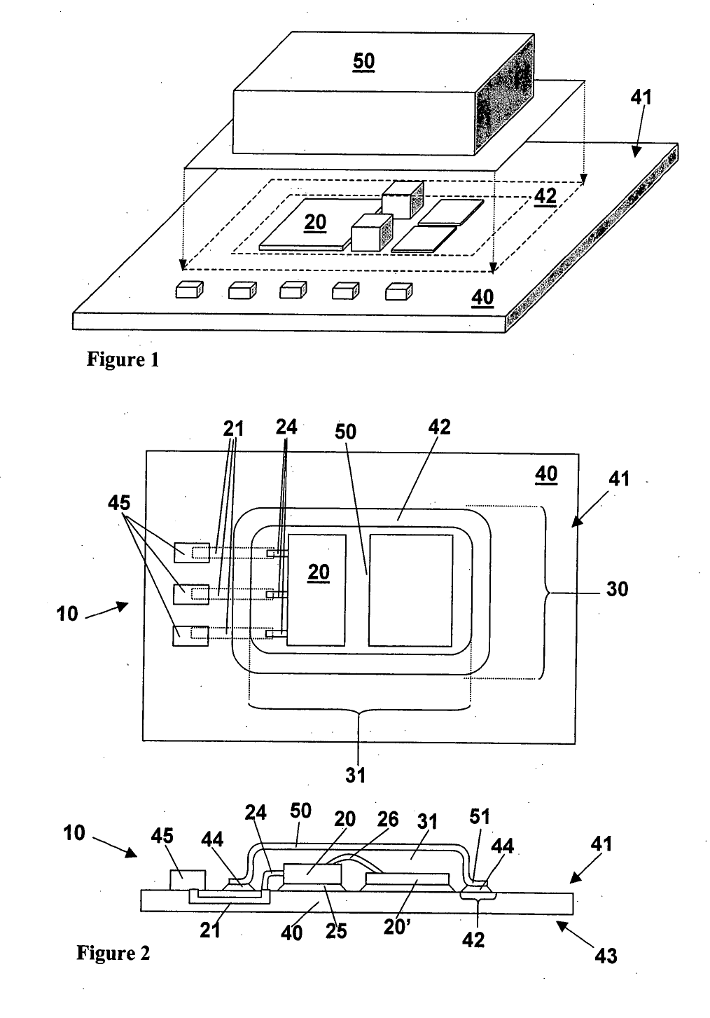

FIG. 1 shows a schematic illustration of a preliminary stage, having a cover which is still unmounted, of a device according to the present invention for passivating at least one component 20. A housing (see FIGS. 2 through 4), which is partially formed by a cover 50 and partially by a substrate 40, is implemented to passivate component 20. Substrate 40 has a front side 41. Cover 50 is implemented as a metal cap, for example, and is connected to substrate 40 on front side 41 of substrate 40 in a connection area 42. In this way, an inner chamber arises in the housing (also see FIGS. 2 through 4).

FIG. 2 schematically shows a top view (upper part of FIG. 2) and a sectional illustration (lower part of FIG. 2) of device 10 according to the present invention. A housing 30 is implemented to passivate at least one component 20 in that cover 50 is connected to front side 41 of substrate 40 and forms inner chamber 31 of housing 30. Cover 50 is illustrated in a transparent manner in the upper part of FIG. 2, so that inner chamber 31 of housing 30 can be seen in the top view. It may be seen in particular from the sectional illustration in the lower part of FIG. 2 that front side 41 of substrate 40 has a connection area 42, which peripherally encloses the area of component 20 and/or multiple components 20, 20′. Cover 50 is connected using a boundary area 51 of cover 50 to substrate 40 via connection area 42. A first connection 44, which may be provided in particular as soldered, welded, and/or glued, is used for this purpose. A second connection 25 is used to attach and/or contact and/or thermally connect component 20 and/or a further component 20′ to substrate 40, in particular to front side 41 of substrate 40. Multiple components 20, 20′ may be electrically connected and/or contacted in an electrically conductive manner in interior chamber 31 of housing 30 via bonding wires, identified by reference numeral 26 as an example, or similar further connections. These components may be complete assemblies including sensors, analyzer circuits, resistors, and capacitors. For example, component 20 is electrically connected to a contact line 21 via a terminal 24 and this line is in turn connected in an electrically conductive manner to a contact element 45 outside housing 30. According to the example embodiment of the present invention, contact line 21 is electrically insulated from connection area 42 in the proximity of at least a part of connection area 42 between front side 41 and a rear side 43 of substrate 40. It is possible in this way to produce electrical contacting of component 20 through connection area 42 and/or through a projection of connection area 42 via substrate 40, without electrically conductive contacting of connection area 42 occurring and without impairing the seal of housing 30.

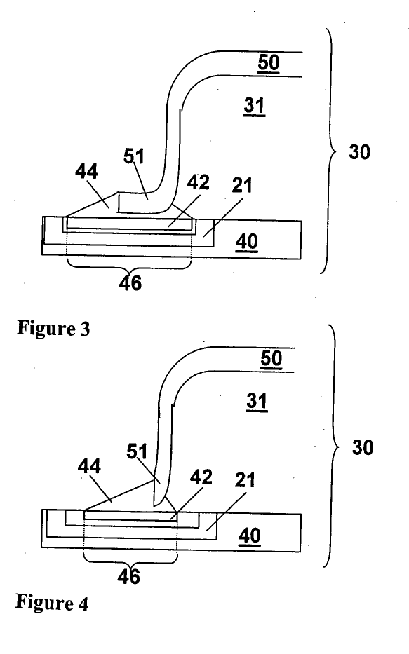

A first embodiment of the connection of cover 50 to substrate 40 to form housing 30 is illustrated in FIG. 3. Boundary area 51 of cover 50 is provided generally parallel to front side 41 of substrate 40, so that a planar contact results in connection area 42 between cover 50 and substrate 40. Furthermore, first connection 44 between cover 50 and connection area 42 on front side 41 of substrate 40 is recognizable.

A second example embodiment of a connection of cover 50 to front side 41 of substrate 40 is illustrated in FIG. 4. Boundary area 51 of the cover is essentially tapered to a point on front side 41 of substrate 40 (and/or having a narrow cap border) in the second embodiment, so that the contact between cover 50 and substrate 40 via connection area 42 is provided generally linearly, first connection 44 also being shown in the second embodiment.

In both embodiments of the connection of cover 50 to substrate 40 to form housing 30, contact line 21 (and/or multiple contact lines 21) may be guided through substrate 40 through the area of a projection 46 of connection area 42. It is thus possible to implement contacting of component 20 and/or of specific terminal lines of component 20 outside housing 30.

According to the example embodiment of the present invention, cover 50 is connected to substrate 40 in such way that inner chamber 31 of housing 30 may be hermetically sealed off from the exterior of housing 30. This allows the inner chamber of housing 30 to be settable with a predefined atmosphere, in particular with a predefined ambient humidity and/or a predefined dew point and in particular with a predefined gas pressure. According to the example embodiment of the present invention, this may also be ensured over the entire service life of device 10—which may be many years (up to 10 or 20 years, for example) if device 10 is used in the framework of a vehicle application. Furthermore, it is possible in this way for component 20 to be provided as a sensor component which has a micromechanical structure, for example, which is not passivated in another way in addition to the passivation caused by housing 30. In particular, speed and/or acceleration sensors may be applied as a “bare die” without further protection by a gel or the like, for example. It may be particularly important according to the present invention that the materials of cover 50 and substrate 40 are provided in such a way that their coefficients of thermal expansion are tailored to one another. This greatly increases the reliability of the hermetic seal of housing 30, in particular in regard to temperature changes. It is particularly advantageous if substrate 40 is provided as an LTCC ceramic (low temperature co-fired ceramic). Furthermore, it is particularly advantageous for first connection 44 to be provided as a soldered connection, so that cover 50 may be attached to substrate 40 using a typical soldering process. The gas atmosphere in inner chamber 31 of housing 30 must be set during the soldering process by providing an appropriate ambient humidity and/or an appropriate atmosphere and/or a defined gas pressure during the soldering process. According to the present invention, it is advantageous in particular if cover 50 is manufactured from an iron-nickel material FeNi 42 and substrate 40 is manufactured from an LTCC ceramic.

1-7. (canceled)

8. A device for passivating at least one component by a housing, comprising:
a cover connected to a front side of a substrate in a connection area to form an inner chamber of the housing, the component being attached to the front side of the substrate and inside the inner chamber of the housing;
at least one contact line connected in an electrically conductive manner to the component, the at least one contact line being electrically insulated in relation to the connection area and being provided in a proximity of at least a part of the connection area one of: i) between the front side and a rear side of the substrate, which faces away from the front side of the substrate, or ii) on the rear side of the substrate.

9. The device as recited in claim 8, wherein the housing is hermetically sealed.

10. The device as recited in claim 8, wherein a predefined atmosphere is settable in the inner chamber of the housing.

11. The device as recited in claim 8, wherein an atmosphere of the inner chamber has at least one of a predefined or air humidity and predefined dew point.

12. The device as recited in claim 8, wherein an atmosphere of the inner chamber has a predefined gas pressure.

13. The device as recited in claim 8, wherein the substrate is a circuit board.

14. The device as recited in claim 8, wherein the substrate is a ceramic circuit board.

15. The device as recited in claim 8, wherein the substrate is an LTCC ceramic circuit board.

16. The device as recited in claim 8, wherein the connection area is provided peripherally on an edge of the cover.

17. The device as recited in claim 8, wherein the housing is closed in the connection area via at least one of soldering, welding, and adhesion.

18. A method for manufacturing a device comprising:
attaching a component to a front side of a substrate; and
connecting a cover to the front side of the substrate in a connection area to form an inner chamber of a housing, the component being inside the inner chamber of the housing;
wherein at least one contact line is connected in an electrically conductive manner to the component, the at least one contact line being electrically insulated in relation to the connection area and being provided in a proximity of at least a part of the connection area between the front side and a rear side of the substrate which faces away from the front side, or on the rear side of the substrate.
